(19) United States
(12) Patent Application Publication
(10) Pub. No.: US 2006/0054087 A1
(43) Pub. Date: Mar. 16, 2006

(54) Process chamber for manufacturing seminconductor devices

(76) Inventors: Jung-Hun Seo, Suwon-si (KR); Yun-Ho Choi, Suwon-si (KR); Young-Wook Park, Suwon-si (KR); Jeong-Tae Kim, Sungnam-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/000,941

(22) Filed: Dec. 2, 2004

(30) Foreign Application Priority Data
Dec. 19, 2003 (KR) 2003-93593

(51) Int. Cl. C23C 16/00

(52) U.S. Cl. 118/715; 156/916

(57) ABSTRACT

The present invention is directed to a plasma process chamber capable of maintaining a high vacuum in the idle state. The present invention maintains a high vacuum in the idle state and prevents a contamination of the wafer transferred into the process chamber.

### BACKGROUND OF THE INVENTION

1. The Field of the Invention

The present invention generally relates to an apparatus for fabricating a semiconductor device. More particularly, the present invention relates to a plasma process chamber capable of maintaining high vacuum in an idle state.

A claim of priority is made to Korean Application No. 2003-0093593, the disclosure of which is incorporated herein by reference in its entirety.

2. Description of the Related Art

Generally, fabricating a semiconductor device requires a series of processes. Namely, a wafer is manufactured into a semiconductor device through a series of photolithography, diffusion, etching, and deposition processes. In some semiconductor fabrication processes, plasma is used to etch away an object or deposit material on a wafer. Processes using plasma include etching processes, such as sputter etching or reactive ion etching, and deposition processes such as chemical vapor deposition (CVD).

Etching processes are classified into two categories: wet etching and dry etching. Dry etching includes sputter etching and reactive ion etching. Dry etching involves the injection of a reactant gas into a closed process chamber, applying a high-frequency wave, such as microwaves to the reactant gas to form a plasma state, wherein the plasma etches away an insulation layer or metal films. Dry etching is characterized by anisotropic etching of an insulation layer or metal films without a post-etching cleaning step. Therefore, dry etching is useful in the formation of fine patterns for use within Very Large Scale Integration (VLSI) devices. Dry etching is a simple process and more advantageous as compared to wet etching.

New insulation materials and conductive layers for semiconductor devices have recently been developed with the continuing trend towards miniaturization, lighter, and smaller thickness for various electrical components that characterizes emerging high-density integrated circuits, such as Ultra Large Scale Integration (ULSI) devices. These thin film type devices require highly reliable properties. Hence, there is a need for a method of manufacturing a thin film that satisfies the competing requirements for uniform deposition, excellent step coverage, and complete elimination of fine particles. To achieve this purpose, various thin film deposition methods have been developed, including Chemical Vapor Deposition (CVD) and Physical Vapor Deposition (PVD). The CVD method is superior in regards to better step coverage, high deposition speed, and uniform thickness deposition on a thin film. As a result, the CVD method is widely used in the fabrication of semiconductor devices. Hereinafter, problems associated with conventional CVD processes will be described in some additional detail.

The CVD method forms various types of thin films on a wafer by means of chemical reactions. The CVD method is carried out across a wide temperature range with a high-frequency wave or microwave energy applied to gaseous compounds to form a plasma state. Heating of a semiconductor substrate accelerates the reaction process between the plasma gas and substrate, and also controls the properties of resultant thin films.

A typical, conventional CVD device includes a process chamber, a gas panel, a control unit, a power supplier, and a vacuum pump. An example of a CVD device is disclosed, for example, in U.S. Pat. No. 6,159,299.

A vacuum pump provides a vacuum, as well as maintains adequate gas flow and pressure within the process chamber. The process chamber must maintain vacuum near a vacuum pressure level associated with a transfer module. This is especially true when an inner door connecting the process chamber to the transfer module is opened during an idle state. Such an idle state generally occurs when a processed wafer is transferred to the transfer module from the process chamber, and/or a new (or to-be-processed) wafer is transferred into the process chamber from the transfer module.

However, the high vacuum state of a process chamber is more dependent upon a magnitude of conductance than on the vacuum pump. This is illustrated on FIG. 8. As shown, an increment in pump speed with an increase in pump capacity is insignificant. However, pump speed increases approximately 5.6-fold with an increase in conductance. Conductance corresponds to the size of gas passage related to an external discharge from a process chamber, and the magnitude of pump speed corresponds to high vacuum feasibility.

However, the conventional plasma process chamber has low conductance, therefore it cannot maintain a high vacuum state in an idle state even where the pump capacity is increased. This inability causes two problems.

First, a to-be-processed wafer transferred into the process chamber during an idle state may become contaminated with one or more residual gases. This can be seen from the Residual Gas Analysis (RGS) results shown in FIG. 1. FIG. 1 shows changes in the volume of residual gases (H₂, C₃H₇NH₂, and N₂) in a process chamber over a period of time. When a wafer is transferred into the process chamber during the time period from 0 to 145 seconds, the residual gases penetrate into the wafer and the volume of the gases decreases. On the contrary, when a processed wafer is removed from the process chamber during the time period from 146 to 200 seconds, the volume of residual gases increases. Consequently, when a to-be-processed wafer is transferred into the process chamber it becomes contaminated with residual gases remaining in the process chamber.

Second, when a CVD process is carried out on a contaminated wafer, the material deposited on the wafer is susceptible to degradation. In particular, a so-called grooving effect intensifies. FIG. 2 shows the surface of a material deposited on a wafer after a CVD process in a conventional plasma process chamber. The figure shows a serious degradation in the material deposited on the wafer. In addition, the use of a contaminated wafer in subsequent processes results in various other defects.

### SUMMARY OF THE INVENTION

Therefore, in one aspect, the present invention provides a plasma process chamber capable of maintaining a high vacuum condition by increasing conductance, so as to prevent a to-be-processed wafer moved into the process chamber from becoming contaminated with residual gases in the process chamber.

In another aspect, the present invention provides a plasma process chamber adapted to perform a CVD process with an uncontaminated wafer to prevent a grooving effect and degradation of a material deposited on the wafer.

Accordingly, the present invention provides a process chamber adapted for use with a semiconductor fabrication process. The process chamber includes a wafer support disposed within the process chamber, a showerhead disposed above the wafer support, and a chamber insert disposed between walls of the process chamber and the wafer support and spaced below the showerhead, wherein the chamber insert comprises a hollow cylinder having a protrusion integrally formed at one end thereof, and having at least one opening on a side of the hollow cylinder.

In a related aspect, the process chamber according to the present invention includes a wafer support disposed within the process chamber, a showerhead disposed above the wafer support, a chamber insert disposed between walls of the process chamber and the wafer support and spaced below the showerhead, wherein the chamber insert comprises a hollow cylinder having a protrusion integrally formed at one end thereof, and having a slit positioned at one end and at least one opening positioned on an opposite side of the slit.

According to the present invention, a high vacuum condition can be maintained in an idle state to prevent contamination of a wafer transferred into a process chamber.

### BRIEF DESCRIPTION OF THE DRAWINGS

FIG. 1 shows variations in volume of residual gases in a process chamber when a wafer is transferred into and out of a conventional process chamber;

FIG. 2 shows a surface of a material deposited on a wafer after a CVD process performed in a conventional plasma process chamber;

FIG. 3 is a cross-section of a process chamber according to an embodiment of the present invention;

FIG. 4 is an expanded diagram of the process chamber centering on a chamber insert of FIG. 3;

FIG. 5 is a perspective of the chamber insert of FIGS. 3 and 4;

FIG. 6 is a perspective of a chamber insert according to another embodiment of the present invention;

FIG. 7 shows a surface of a material deposited on a wafer after a deposition process using a process chamber of the present invention; and

FIG. 8 is a table showing variations in pump speed dependent on a pump capacity and conductance.

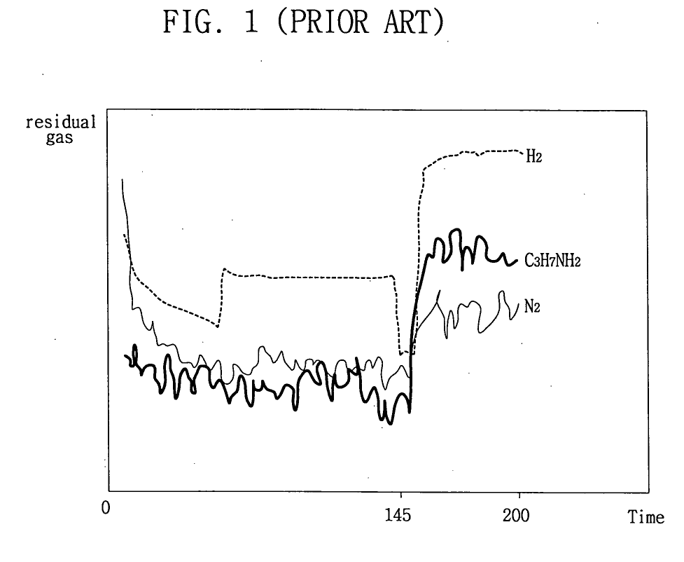

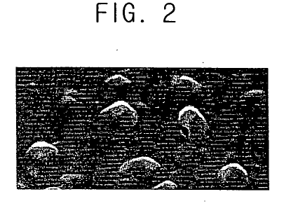

### DETAILED DESCRIPTION OF THE INVENTION

In the following detailed description, selected exemplary embodiments of the present invention are shown and described. As will be realized, these exemplary embodiments are susceptible to modification in various respects, all without departing from the scope of the present invention. Accordingly, the drawings and description are to be regarded as illustrative in nature and not restrictive.

Hereinafter, a process chamber of the present invention performing a CVD process will be described. It will be apparent to those skilled in the art that the process chamber can perform different processes (e.g., etching) other than a CVD process.

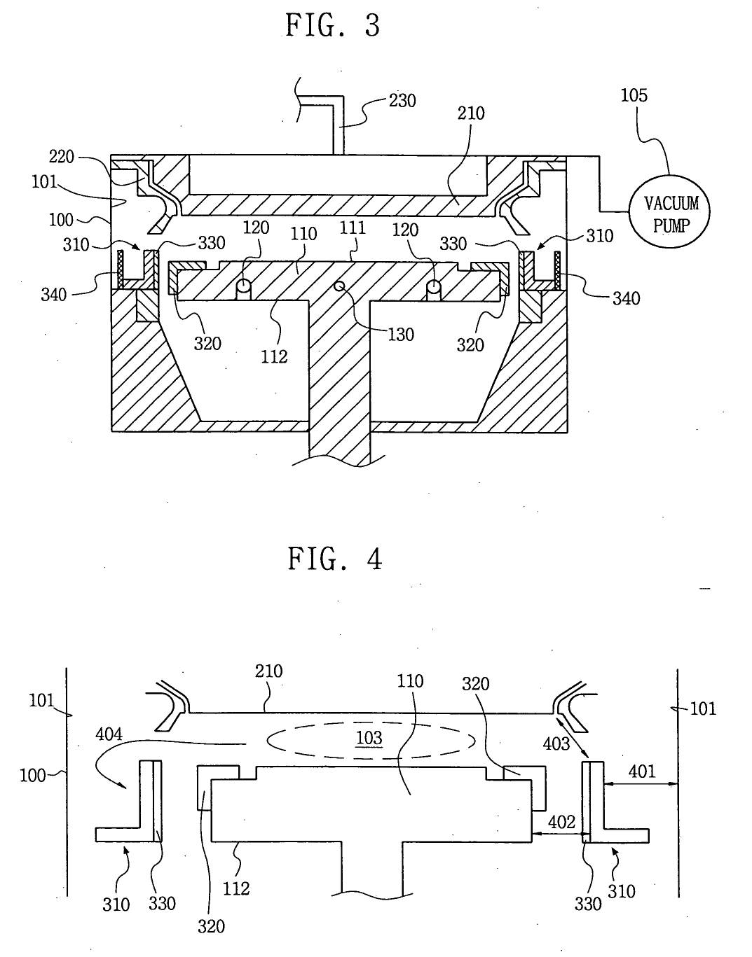

FIG. 3 is a cross-section of a process chamber according to one embodiment of the present invention.

A process chamber 100 includes a wafer support 110, a showerhead 210, and a chamber insert 310.

Wafer support 110 is installed in process chamber 100 and is capable of moving vertically with respect to a displacement apparatus (not shown). Wafer support 110 is typically heated to a predetermined temperature during a CVD process. For this purpose, a wafer supporter 111 comprises a heater 120 provided under wafer support 110. Wafer support 110 may be formed of aluminum, and heater 120 may be formed of a nickel-chrome wire coated with an Incoloy sheath tube. Wafer support 110 preferably comprises a temperature sensor 130 for monitoring temperature. Temperature measured by temperature sensor 130 is used as a feedback signal to control a current output by a heater power supplier (not shown) to maintain and control an adequate temperature level. A purge gas is typically used to prevent any undesired depositions on wafer support 110.

Showerhead 210 has an insulator 220 formed on an outer periphery thereof. Showerhead 210 injects reactant gases onto a surface of a wafer. Reactant gases are supplied through a reactant gas supply line 230, and the reactant gases are injected onto the wafer through holes (not shown) in showerhead 210. The proper control and regulation of the gas flow passing through reactant gas supply line 230 are achieved with a control box (not shown) such as a weight flow controller or a computer. The control box also controls numerous process steps required for the processing of a wafer, such as wafer transport, temperature control, gas discharge, and the like. Generally, the control box has a central processor unit (CPU), various support circuitry, and a related memory storing control software. The control box is well known in the art and will not be described in detail. Reactant gases used to deposit a film on the surface of the wafer are discharged through an exhaust tube (not shown) from process chamber 100 by way of a vacuum pump 105. Vacuum pump 105 controls vacuum state, as well as maintains proper gas flow and pressure within process chamber 100.

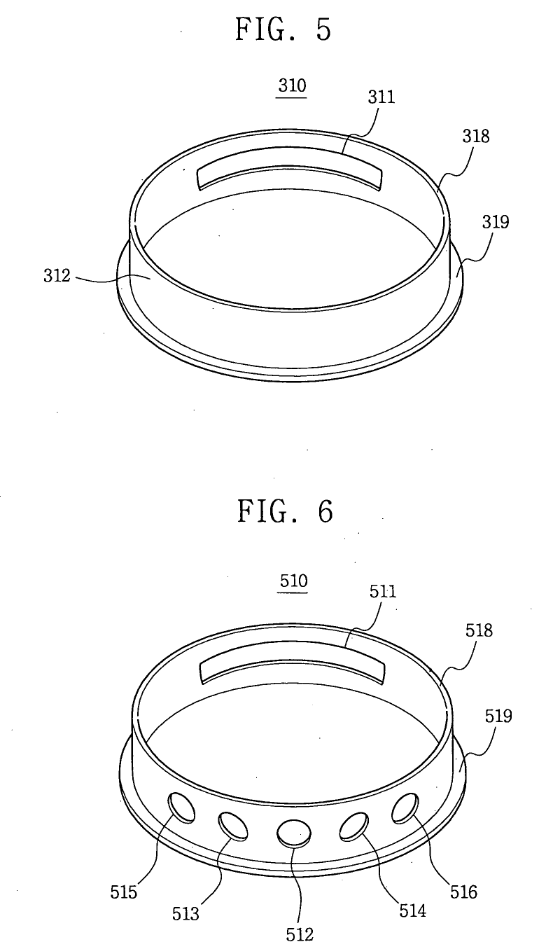

Chamber insert 310 installed apart from showerhead 210 at a predetermined distance, includes a hollow cylinder 318 (see, FIG. 5) having a predetermined diameter, preferably about 330 to 430 mm and a predetermined height, preferably about 40 to 70 mm, and a protrusion 319 integrally formed at one end of the hollow cylinder 318. Chamber insert 310 is located between an inner wall 101 of the process chamber 100 and the wafer support 110 at a distance of about 2 to 30 mm, and preferably at a distance of about 2 to 10 mm. The function of chamber insert 310 will be further described with reference to FIGS. 4 and 5.

Process chamber 100 further includes an edge ring 320, an inner shield 330, and an outer shield 340. Edge ring 320 is attached to surround the edge of wafer support 110, and is formed of stainless steel or aluminum (Al). The surface of the edge ring 320 is formed by bead-blasting to increase the attachment of undesired coating materials. This constitution of edge ring 320 minimizes contamination of the wafer by particles. Inner shield 330 is installed in chamber insert 310 to confine and limit the spread of plasma towards showerhead 210 and wafer support 110. Outer shield 340 is installed outside chamber insert 310 to prevent undesired depositions on inner wall 101. However, outer shield 340 is optional if cooling water is used to prevent undesired depositions.

FIG. 4 is an expanded diagram of the plasma process chamber of FIG. 3 centering on chamber insert 310, and FIG. 5 is a perspective of the hollow cylinder 318 within chamber insert 310 of FIG. 4.

Referring to FIGS. 4 and 5, chamber insert 310 is spaced apart from inner wall 101 by a predetermined distance 401 and from wafer support 110 at a predetermined distance 402. Chamber insert 310 comprises hollow cylinder 318 having a predetermined outer diameter with a predetermined height, and protrusion 319 integrally formed at one end of hollow cylinder 318. A slit 311 allowing transfer of wafers is formed in a lateral side of hollow cylinder 318. Inner shield 330 is installed in an interior of chamber inset 310 and is electrically isolated from inner wall 101. When a wafer (not shown) is transferred into process chamber 100 from a transfer module through slit 311, showerhead 210 injects a reactant gas onto the surface of the wafer. After the deposition process, the reactant gas flows along an outer side of chamber insert 310 and exhausted through the exhaust tube (not shown). The reactant gas flows in a direction of arrow 404 (see, FIG. 4) away from process block 103 and then along the outer side of chamber insert 310. In the conventional process chamber, the flow channel in the direction of arrow 404 is too narrow. The volume of fluid per unit time from the vacuum pump (hereinafter, referred to as “pumping speed”) is insufficient to maintain the process chamber under vacuum. However, according to one embodiment of the present invention, the flow channel in the direction of arrow 404 is relatively wider which means an increase in conductance. The pumping speed increases as conductance is increased, and high vacuum in process chamber 100 is maintained.

An inner door (not shown) connecting process chamber 100 and the transfer module opens when a to-be-processed wafer is transferred into process chamber 100 from the transfer module, and a processed wafer transferred to the transfer module from process chamber 100 (i.e., during an idle state) after a completion of a deposition process. Hence, process chamber 100 must maintain a high vacuum state approximately equal to a vacuum state associated with the transfer module.

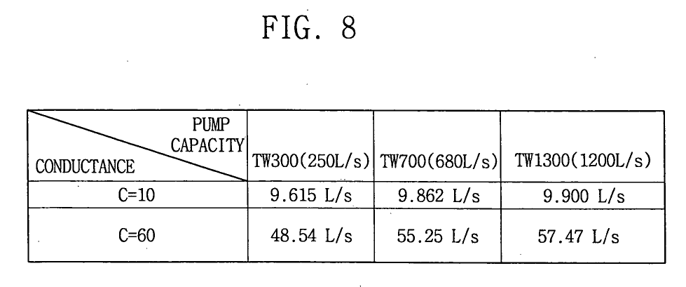

This becomes more apparent with reference to the table of FIG. 8. In the table, the values in the columns represent pump capacity, and values in the rows represent conductance. When conductance is “10” and pump capacity is “250 L/s,” the pumping speed is “9.615 L/s.” At pump capacity of “680 L/s” and conductance of “10”, the pumping speed is “9.862 L/s.” Likewise, at pump capacity of “1200 L/s” and conductance of “10”, the pumping speed is “9.900 L/s.” This shows that an increment of pumping speed is insignificant relative to the increment of pump capacity, and also that the magnitude of pumping speed is not greatly dependent upon pump capacity. Pumping speed is “9.862 L/s” with pump capacity of “680 L/s” and conductance of “10,” while “55.25 L/s” with the same pump capacity of “680 L/s” and conductance of “60.” This indicates that the magnitude of pumping speed is greatly dependent upon conductance. Here, the magnitude of pumping speed indicates whether or not a high vacuum is achieved.

The increment of conductance in process chamber 100 becomes greater with a decrease in the height of hollow cylinder 318. A distance 403 between chamber insert 310 and showerhead 210 increases as the height of hollow cylinder 318 decreases, this means an increase in conductance, resulting in a rise of pumping speed. The height of hollow cylinder 318 is preferably in a range of about 40 to 70 mm, and more preferably in a range of about 2 to 30 mm. It is apparent to those skilled in the art that the distance between the chamber insert 310 and showerhead 210 can also be controlled by other factors such as the profile of showerhead 210.

In addition, conductance can be increased by widening distance 401 between the chamber insert 310 and inner wall 101. In other words, the volume of fluid per unit time through the flow channel in the direction of arrow 404 increases with an increase in distance 401. The distance between chamber insert 310 and inner wall 101 in this case is preferably in the range of about 2 to 30 mm.

On the other hand, chamber insert 310 preferably has a distance of about 2 to 10 mm from wafer support 110. The distance reduction between chamber insert 310 and wafer support 110 can prevent an undesired deposition on a bottom face 112 of wafer support 110 and an associated lift pin (not shown).

FIG. 6 is a perspective of a chamber insert according to another embodiment of the present invention.

Referring to FIG. 6, a chamber insert 510 includes a hollow cylinder 518 having a predetermined diameter and a predetermined height, and a protrusion 519 integrally formed at one end of cylinder 518. A slit 511 is formed in one lateral side of hollow cylinder 518. Opposite slit 511, at least two openings having a predetermined diameter and spaced apart from each other at a predetermined distance are formed. In this embodiment, the number of openings is five (5). A second opening 512 is formed opposite of slit 511. Each of third and fourth openings 513 and 514 is formed apart from second opening 512 at a predetermined distance on either side. Fifth and sixth openings 515 and 516 are formed apart from third and fourth holes 513 and 514 at a predetermined distance, respectively. Each of second to sixth holes 512 to 516 has a diameter of about 1 to 50 mm. The diameters of each of second to sixth holes 512 to 516 may differ from each other. For example, holes close to a pumping port (not shown) may have a smaller diameter than the others. Second to sixth holes 512 to 516 also have apertures (not shown) to open/close. Slit hole 511 is a passage through which processed wafer (not shown) after a deposition process is transferred to the transfer module (not shown) from process chamber 100, with a to-be-processed wafer transferred to process chamber 100 from the transfer module. After the wafer is transferred into process chamber 100, showerhead 210 injects a reactant gas onto the surface of the wafer. The residual reactant gas is exhausted by a vacuum pump 105. Second to sixth holes 512 to 516 open to a proper diameter to counter balances slit 511 and prevent a rapid and uneven discharge of the reactant gas through slit 511, thus preventing damage to the wafer caused by the rapid and uneven discharge of the gases.

In another measure to prevent damage to the wafer due to a rapid discharge of reactant gas from slit (311, 511) a distance between one lateral side of chamber insert (310, 510) and inner wall 101 is shorter than a distance between the other lateral side of chamber insert (310, 510) and the other inner wall 101. Namely, a distance between the lateral side having slit (311, 511) and inner wall 101 is closer than the opposite lateral side to inner wall 101. This reduces conductance around slit (311, 511) therefore, reactant gas cannot be discharged too rapidly through slit (311, 511), thereby preventing damages on a wafer. In addition, the use of an uncontaminated wafer in a CVD process can prevent a degradation of the material deposited and prevent a grooving effect.

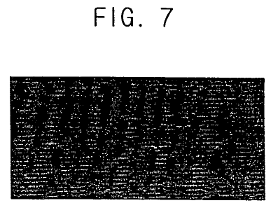

FIG. 7 shows the surface of a material deposited on a wafer after a deposition process using plasma process chamber 100 of the present invention.

FIG. 7 shows uniform deposition on a surface of wafer.

The plasma process chamber according to the foregoing embodiments of the present invention maintains high vacuum in an idle state.

While this invention has been described in connection with presently preferred, exemplary embodiments, it is to be understood that the invention is not limited to only the disclosed embodiments. On the contrary, the present invention encompasses various modifications and equivalent arrangements included within the scope of the appended claims. For example, the present invention is applicable to the etching process as well as the described CVD process.

What is claimed is:

1. A process chamber, comprising:
a wafer support disposed within the process chamber;
a showerhead disposed above the wafer support; and
a chamber insert disposed between walls of the process chamber and the wafer support and spaced below the showerhead, wherein the chamber insert comprises a hollow cylinder having a protrusion integrally formed at one end thereof, and having at least one opening on a side of the hollow cylinder.

2. The process chamber of claim 1, wherein a distance between the chamber insert and the walls of the process chamber is about 2 to 30 mm.

3. The process chamber of claim 2, wherein a distance between the chamber insert and the walls of the process chamber is about 2 to 10 mm.

4. The process chamber of claim 1, wherein a distance between the chamber insert and the showerhead is about 2 to 30 mm.

5. The process chamber of claim 1, wherein a diameter of the hollow cylinder is about 330 to 430 mm.

6. The process chamber of claim 1, wherein a height of the hollow cylinder is about 40 to 70 mm.

7. The process chamber of claim 1, wherein the at least one opening has a diameter of about 1 to 50 mm.

8. The process chamber of claim 1, wherein the at least one opening comprises a plurality of openings.

9. The process chamber of claim 8, wherein one of the plurality of openings comprises a slit formed in one side of the hollow cylinder and other openings in the plurality of openings comprising one or more holes formed in a side of the hollow cylinder opposite the slit.

10. The process chamber of claim 9, wherein the one or more holes vary in size.

11. The process chamber of claim 9, wherein a distance between a wall of the process chamber and a side of the chamber insert having the slit is shorter than the distance between a wall of the process chamber and a side of the chamber insert having the other openings.

12. The process chamber of claim 10, wherein each of the one or more holes has a different diameter.

13. The process chamber of claim 1, wherein a distance between one side of the chamber insert and the wall of the process chamber is shorter than a distance between an opposite side of the chamber insert and the wall of the process chamber.

14. The process chamber of claim 1, wherein the process chamber is a CVD chamber.

15. The process chamber of claim 1, wherein the process chamber is an etching chamber.

16. A process chamber, comprising:
a wafer support disposed within the process chamber;
a showerhead disposed above the wafer support; and
a chamber insert disposed between walls of the process chamber and the wafer support, and spaced below the showerhead, wherein the chamber insert comprises a hollow cylinder having a protrusion integrally formed at one end thereof, and further comprising slit formed in one side and at least one opening formed in an opposite side.

17. The process chamber of claim 16, wherein a distance between the chamber insert and the walls of the process chamber is about 2 to 30 mm.

18. The process chamber of claim 17, wherein a distance between the chamber insert and the walls of the process chamber is about 2 to 10 mm.

19. The process chamber of claim 16, wherein a distance between the chamber insert and the showerhead is about 2 to 30 mm.

20. The process chamber of claim 16, wherein a diameter of the hollow cylinder is about 330 to 430 mm.

21. The process chamber of claim 16, wherein a height of the hollow cylinder is about 40 to 70 mm.

22. The process chamber of claim 16, wherein the opening has a diameter of about 1 to 50 mm.

23. The process chamber of claim 16, wherein a number of the opening is 5.

24. The process chamber of claim 16, wherein the opening is an aperture capable adjusting a size of its opening.

25. The process chamber of claim 1, wherein a distance between a wall of the process chamber and a side of the chamber insert having the slit is shorter than the distance between a wall of the process chamber and a side of the chamber insert having the opening.

26. The process chamber of claim 23, wherein each of the openings have different diameters.

27. The process chamber of claim 16, wherein the process chamber is a CVD chamber.

28. The process chamber of claim 16, wherein the process chamber is an etching chamber.
